(19) United States
(12) Patent Application Publication
(10) Pub. No.: US 2026/0206215 A1
(43) Pub. Date: Jul. 16, 2026

(54) EMBEDDED SILICON GERMANIUM WITH IMPLANT THROUGH SPACER FLOW

(71) Applicant: Micron Technology, Inc., Boise, ID (US)

(72) Inventors: Huajie Chen, Boise, ID (US); Bingwu Liu, Meridian, ID (US); Ronald Allen Weimer, Boise, ID (US); Yong Seung Kim, Boise, ID (US); Saba Sharikadze, Nampa, ID (US); Shivani Srivastava, Boise, ID (US); Dan Mihai Mocuta, Boise, ID (US)

(21) Appl. No.: 19/020,595

(22) Filed: Jan. 14, 2025

(51) Int. Cl. H10B 12/00

(52) U.S. Cl. CPC H10B 12/50

(57) ABSTRACT

A variety of applications can include an electronic device having a transistor with embedded silicon germanium underneath spacers without divots to the active areas of the transistors underneath the spacers. The spacers can be structured on and contacting sidewalls of the gate stacks of the transistors. The lack of divots provides the contact of the spacers to the active areas without an oxide or with a thin native oxide and provides a uniform channel-structure-to-drain interface. A transistor of the electronic can have a silicon germanium channel structure under a gate dielectric with extensions laterally from the ends of the gate dielectric and an embedded silicon germanium source/drain contacting an extension of the silicon germanium channel structure, with a spacer on and contacting the extension, with the spacer being structured without an oxide contacting the extension or with a thin native oxide between and contacting the spacer and the extension.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a structure including a formation of a divot in a transistor having a silicon germanium channel structure and an embedded silicon germanium source/drain, in

accordance with various embodiments.

FIG. 2 is a flow diagram of features of an example method of forming an electronic device, in accordance with various embodiments.

FIG. 3 is a flow diagram of features of an example method of forming an electronic device, in accordance with various embodiments.

FIGS. 4-11 illustrate an example process flow for fabricating an electronic device having a transistor with embedded silicon germanium, in accordance with various embodiments.

FIG. 12 represents the lattice structure for a Si (100) substrate in the <110> direction, in accordance with various embodiments.

FIG. 13 represents the lattice structure for the Si (100) substrate in the <100> direction, in accordance with various embodiments.

FIG. 14 is a schematic of an example dynamic random-access memory device that can include an architecture in which transistors in the periphery to the memory array of the dynamic random-access memory device are structured with spacers on and contacting sidewalls of the gate stacks of the transistors without divots to the active areas of the transistors underneath the spacers, in accordance with various embodiments.

FIG. 15 is a block diagram of an example machine having one or more transistor components with spacers on and contacting sidewalls of the gate stacks of the transistors without divots to the active areas of the transistors underneath the spacers, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In a p-type metal oxide semiconductor field effect transistor (P-MOSFET also known as a PMOS transistor), embedded silicon germanium (eSiGe) can be used to create uniaxial stress in the channel structure of the PMOS transistor to enhance device performance. The PMOS transistor typically includes a dielectric cap on top of a gate stack and a spacer along the vertical walls of the gate stack. A spacer is a dielectric region providing electrical insulation and can provide processing protection to the structure to which it is formed as a spacer. The dielectric cap can typically be a nitride cap and the spacer can typically be a spacer nitride. The nitride cap can be deposited before a gate stack etch, where the nitride cap becomes thinner during the gate stack etch. After nitride cap deposition, the spacer nitride can be deposited followed by performing a spacer etch. The spacer nitride material deposited on top of the gate can be etched away during a spacer etch, with the nitride cap being thinned by a small amount during the spacer nitride etch. The gate stack can include a gate dielectric and a gate on and contacting the gate dielectric with a metal contact region on the gate. The gate of the PMOS transistor can be realized as a metal or a conductive semiconductor such as polysilicon. The metal contact region can extend in a horizontal direction to couple to a potential source. In a conventional process flow for forming a spacer for the PMOS transistor, such as in, but not limited to, the periphery to a memory array of a memory device, the active areas for the PMOS transistor, which are exposed during implants for lightly doped drain (LDD) regions and Halo regions, are oxidized during a resist strip. The resist strip is conducted after the implantation to remove photo resist used in the implantation process. The PMOS active area can be a Si or a SiGe structure. A LDD region is a narrow lightly doped region provided between a channel structure and more heavily doped source-drain regions of a MOSFET. LDD regions are extensions of the more heavily doped source-drain regions to the channel structure. Halo regions of a MOSFET are lightly doped regions near source-drain regions to reduce the width of the depletion region in the vicinity of source/substrate and drain/substrate junctions.

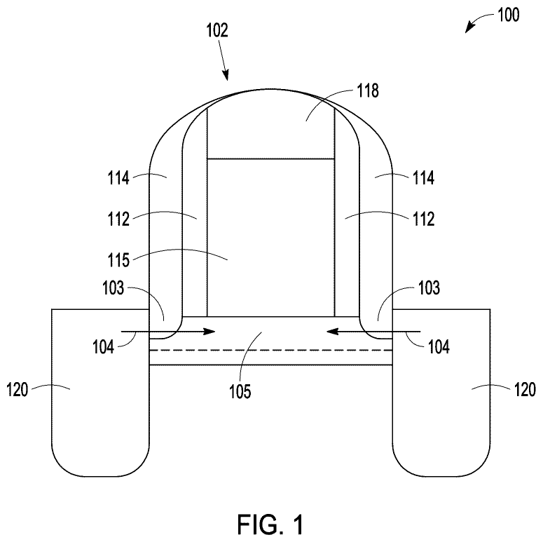

In a design having a SiGe channel (cSiGe) structure for a PMOS transistor, the oxidation of the cSiGe causes a divot underneath an additional spacer deposed beside an initial spacer, where the additional spacer is along the gate stack. The first spacer can be a nitride spacer, and the additional spacer can be a second nitride spacer. The second spacer can be used as a hard mask to cover device areas that do not have eSiGe, such as but not limited to n-type MOS (NMOS) transistors situated in the device, while forming a spacer along a gate stack on the device areas that have an eSiGe. The second spacer is used to control proximity of the eSiGe to the channel structure of the transistor. The divot can reduce the strain transfer from the eSiGe to the cSiGe and thus reduce the device performance benefit of eSiGe. See, for example, FIG. 1, which illustrates the formation of a divot with respect to the additional spacer. The divot can also potentially affect the epitaxial quality of the eSiGe.

FIG. 1 illustrates a structure 100 during formation of a transistor 102 in an integrated circuit including a formation of divots 103 in transistor 102 having a cSiGe structure 105 and eSiGe source/drains 120. Transistor 102 can be a PMOS transistor. Transistor 102 can include a gate stack 115 with first spacers 112 beside the side walls of gate stack 115 and a dielectric cap 118 on the top of gate stack 115, with second spacers 114 beside first spacers 112. The composition of first spacers 112 and dielectric cap 118 can be the same. With transistor 102 being a PMOS transistor having cSiGe structure 105 and eSiGe source/drains 120, there are strain transfers 104 from eSiGe source/drains 120 to cSiGe structure 105. However, in the conventional formation, divots 103 in second spacers 114, due to SiGe oxidation, have been formed at the bottom of second spacers 114. Strain transfers 104 from eSiGe source/drains 120 to cSiGe structure 105 are partially blocked by divots 103 in second spacers 114.

In various embodiments, one or more transistors of a device are structured having surfaces of active areas, where the active areas are coupled by channel structures, without an oxide of the surface material on and contacting the surfaces or with a native oxide, having a thickness less than about one nanometer. The device can be a memory device. In a spacer process flow, in which a first spacer is formed on and along walls of the gate stacks of the one or more transistors, a LDD/Halo implant-through-spacer integration scheme leaves the first spacer unetched to provide for subsequent LDD/Halo implants being directed through the first spacer. The first spacer can be, but is not limited to, a spacer nitride that can also be formed on substantially horizonal surfaces adjacent to gate stacks of the one or more transistors. The active area (Si or SiGe) can be protected by the first spacer from oxidation during subsequent resist stripping that may be associated with LDD/Halo implants. A second spacer can be deposited after LDD/Halo implants are provided. The LDD/Halo-implant-through-spacer integration scheme can achieve a straight cSiGe sidewall without a divot underneath the second spacer of the two spacers formed, thus enhancing the strain transfer. The second spacer, in addition to the first spacer, can be, but is not limited to, a nitride spacer. Both the first and second spacers can be etched during subsequent spacer etching after eSiGe formation for selected ones of the one or more transistors in the device. The transistor devices with eSiGe source/drains can be protected with photo resist during spacer etching step that etches the first and second spacers. Source and drain implants for transistor devices that are without eSiGe can be introduced afterwards.

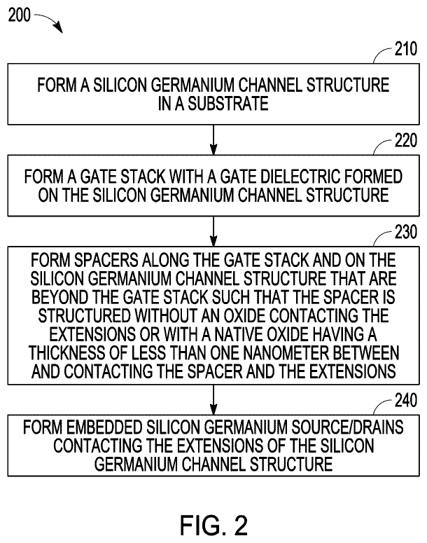

FIG. 2 is a flow diagram of features of an embodiment of an example method 200 of forming an electronic device including forming a transistor. At 210, a cSiGe structure for the transistor is formed in a substrate. At 220, a gate stack is formed with a gate dielectric formed on the cSiGe structure. The gate stack can have a polysilicon region on the gate dielectric. At 230, a spacer is formed along the gate stack and on extensions of the cSiGe structure that are beyond the gate stack. The spacer is structured without an oxide contacting the extensions or with a native oxide having a thickness of less than about one nanometer between and contacting the spacer and the extensions. At 240, eSiGe source/drains are formed contacting the extensions of the cSiGe structure. The cSiGe structure at the contacts of the extensions with the eSiGe source/drains can achieve straight cSiGe sidewalls without divots underneath the spacer.

Variations of method 200 or methods similar to method 200 can include a number of different embodiments that may be combined depending on the application of such methods or the architecture or process flow of an integrated circuit for which such methods are implemented. Such methods can include doping through an initial spacer on the extensions of the silicon germanium channel structure after forming the gate stack and before forming a second spacer on the extensions of the silicon germanium channel structure.

Variations of method 200 or methods similar to method 200 can include depositing materials for the gate stack and etching the deposition materials to form the gate stack. In forming the spacer, a first spacer can be formed along the gate stack and on the extensions of the cSiGe structure, followed by LDD and Halo implants through the first spacer. In further forming the spacer, a second spacer can be deposited on the first spacer. The first and second spacers can be etched, followed by or including a trench etch in which the eSiGe source/drains can be formed.

Variations of method 200 or methods similar to method 200 can include forming the transistor in a periphery circuit of a memory device and forming a n-type transistor in the periphery circuit including forming the n-type transistor having a gate dielectric in a gate stack with a spacer adjacent and contacting the gate stack of the n-type transistor, where the spacer is structured without an oxide on and contacting LDD regions of the n-type transistor or with a native oxide having a thickness of less than about one nanometer between and contacting the spacer and the LDD regions of the n-type transistor. Periphery circuits include logic-like device components that basically control the memory circuits of the memory device.

Variations of method 200 or methods similar to method 200 can include forming the transistor in a periphery circuit of a memory device and forming a pitch transistor having a gate dielectric in a gate stack with a spacer adjacent and contacting the gate stack of the pitch transistor, where the spacer is structured without an oxide on and contacting LDD regions of the pitch transistor or with a native oxide having a thickness of less than about one nanometer between and contacting the spacer and the LDD regions of the pitch transistor. Pitch circuits include circuits which can have dimensions aligned with the memory array, such as word line drivers, sense amplifiers, or other similar circuits.

The techniques of method 200 can be applied to forming other transistor structures that use materials different from SiGe for a channel structure and for an embedded structure to provide a strain transfer to the channel structure. The channel structure may be realized by a first material and embedded drain/source regions may be realized by a second material that can be structured to provide strain transfer to the first material to enhance transistor properties of the transistor structured with the first and second material.

In various embodiments, an electronic device can include a transistor having a cSiGe structure and a gate stack with a gate dielectric on the cSiGe structure. The transistor can include a spacer along the gate stack and on an extension of the cSiGe structure beyond the gate stack such that the spacer is structured without an oxide contacting the extensions or with a native oxide having a thickness of less than about one nanometer between and contacting the spacers and the extensions. The extensions of the cSiGe structure beyond the gate stack can be LDD regions. The transistor can include eSiGe source/drains contacting the extensions of the silicon germanium channel structure. The transistor can be located in a periphery to a memory array of a memory device. The memory device can be, but is not limited to, a DRAM device.

Variations of such an electronic device and its features, as taught herein, can include a number of different embodiments and features that may be combined depending on the application of such electronic devices, the format of such electronic devices, and/or the architecture in which such electronic devices are implemented. Features of such electronic devices can include the periphery to a memory device structured to contain the transistor and to contain a n-type transistor having a gate dielectric in a gate stack with a spacer adjacent and contacting the gate stack, where the spacer is structured without an oxide on and contacting LDD regions of the n-type transistor or with a native oxide having a thickness of less than about one nanometer between and contacting the spacer and the LDD regions of the n-type transistor. A variation can include the transistor and the n-type transistor structured as part of a periphery circuit. Variations can include the periphery having a pitch transistor of a pitch circuit, where the pitch transistor has a gate dielectric in a gate stack with a spacer adjacent and contacting the gate stack. The spacer for the pitch transistor can be structured without an oxide on and contacting LDD regions of the pitch transistor or with a native oxide having a thickness of less than about one nanometer between and contacting the spacer and the LDD regions of the pitch transistor.

Variation of such an electronic device and its features can include the gate dielectric being an oxide in a gate stack. The gate stack can have a polysilicon gate on the gate dielectric and a metal on the polysilicon gate. Variations can include the silicon germanium channel structure of the transistor being in the <100> direction or the <110> direction with respect to a silicon substrate in which the transistor is structured. Variations of such an electronic device and its features can be structured with the spacer of the transistor including a nitride. Variations can include the spacer structured as a combination of two spacers. The two spacers can have a common composition. The common composition can include a nitride.

Other transistor structures can be used for the electronic device in which materials different from SiGe can be used for a channel structure and for an embedded structure to provide a strain transfer to the channel structure. The channel structure may be realized by a first material and embedded drain/source regions may be realized by a second material that can be structured to provide strain transfer to the first material to enhance transistor properties of the transistor structured with the first and second material.

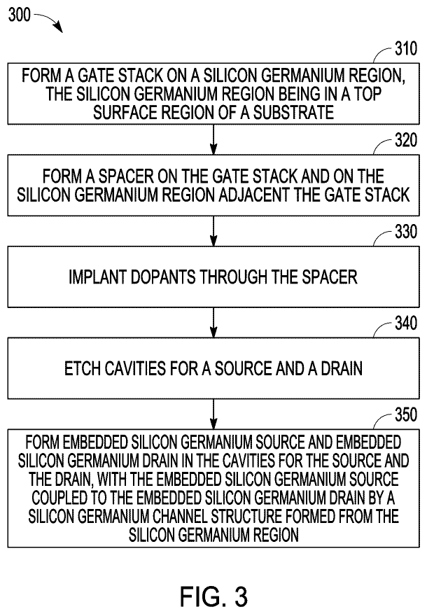

FIG. 3 is a flow diagram of features of an embodiment of an example method 300 of forming an electronic device including forming a transistor. At 310, a gate stack is formed on a SiGe region, where the SiGe region is in a top surface region of a substrate. At 320, a spacer is formed on the gate stack and on the SiGe region adjacent the gate stack. The spacer can be, but is not limited to, a deposited spacer nitride. At 330, dopants are implanted through the spacer. At 340, cavities are etched for source/drain regions. At 350, an eSiGe source and an eSiGe drain are formed in the formed cavities for the source and drain, with the eSiGe source coupled to the eSiGe drain by a cSiGe structure formed from the SiGe region.

Variations of method 300 or methods similar to method 300 can include a number of different embodiments that may be combined depending on the application of such methods or the architecture or process flow of an integrated circuit for which such methods are implemented. Such methods can include forming a hard mask on the gate stack and on the spacer before forming the regions for the source and the drain. The hard mask can be patterned, which can be used in forming the cavities for the source and the drain such that a wall of each cavity includes an end of the SiGe region extending from the gate stack.

Variations of method 300 or methods similar to method 300 can include forming a second spacer on the spacer after implanting the dopants through the spacer. The second spacer can be, but is not limited to, a deposited nitride. A photolithography procedure can be performed to protect devices on the substrate that are non-eSiGe devices such as, but not limited to, NMOS transistors. The spacer and the second spacer can be etched, followed by or including a trench etch in which the eSiGe source/drains can be formed.

Variations of method 300 or methods similar to method 300 can include forming one or more transistors without SiGe while forming the transistor, such that the one or more transistors have material of a spacer on and contacting LDD regions of the one or more transistors without an oxide on or with a native oxide having a thickness of less than about one nanometer between and contacting the material of the spacer and the LDD regions of the one or more transistors. Variations can include implanting dopants in the one or more transistors that are different from the dopants implanted through the spacer.

Variations of method 300 or methods similar to method 300 can include implanting dopants through the spacer such that a lightly doped drain region and a Halo structure are formed. Variations can include forming a high-k metal gate (HKMG) in the gate stack. A HKMG is a gate having a metal located on a high-k dielectric, where a high-k dielectric is a dielectric having a dielectric constant greater than that of silicon dioxide. The high-k dielectric can be located on a thin layer of silicon oxide, forming the gate dielectric of the gate stack.

The techniques of method 300 can be applied to forming other transistor structures that use materials different from SiGe for a channel structure and for an embedded structure to provide a strain transfer to the channel structure. The channel structure may be realized by a first material and embedded drain/source regions may be realized by a second material that can be structured to provide strain transfer to the first material to enhance transistor properties of the transistor structured with the first and second material.

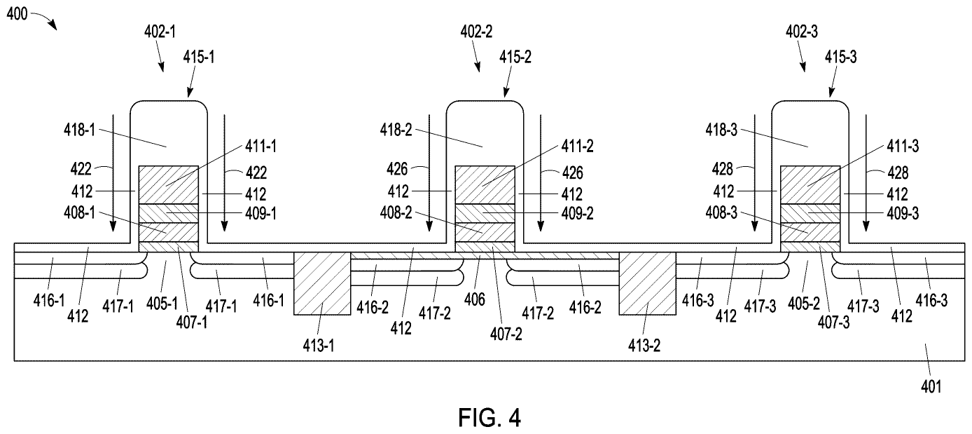

FIGS. 4-11 illustrate an embodiment of an example process flow for fabricating an electronic device having a transistor with embedded silicon germanium. Though FIGS. 4-10 illustrate three transistors as being fabricated, significantly more than three transistors can be formed in the fabricating of a selected electronic device.

FIG. 4 illustrates a cross-sectional view of a structure 400 after formation of gates stacks 415-1, 415-2, and 415-3 for transistors 402-1, 402-2, and 402-3, respectively, on a substrate 401. Formation of gate stack 415-1 on a channel structure 405-1 in substrate 401 has included forming a gate dielectric 407-1 on channel structure 405-1 and forming a gate 408-1 on gate dielectric 407-1. A polysilicon region 409-1 has been formed on gate 408-1 and a metal contact 411-1 has been formed on polysilicon region 409-1. Formation of gate stack 415-2 on a channel structure 406 in substrate 401 has included forming a gate dielectric 407-2 on channel structure 406 and forming a gate 408-2 on gate dielectric 407-2. A polysilicon region 409-2 has been formed on gate 408-2 and a metal contact 411-2 has been formed on polysilicon region 409-2. Formation of gate stack 415-3 on a channel structure 405-2 in substrate 401 has included forming a gate dielectric 407-3 on channel structure 405-2 and forming a gate 408-3 on gate dielectric 407-3. A polysilicon region 409-3 has been formed on gate 408-3 and a metal contact 411-3 has been formed on polysilicon region 409-3. A shallow trench insulator (STI) 413-1 has been formed separating the region for transistor 402-1 from the region for transistor 402-2. A STI 413-2 has been formed separating the region for transistor 402-2 from the region for transistor 402-3. These devices of FIG. 4 are for illustration purpose and these devices may not be next to each other on a chip.

For a silicon substrate used for substrate 401, channel structures 405-1 and 405-3 can be silicon channel structures. A SiGe region has been formed at the surface region of substrate 401 between STIs 413-1 and 413-2. The SiGe region can be formed as an epitaxial growth from substrate 401. A channel structure can be constructed as a portion of the SiGe region formed in substrate 401, forming a cSiGe structure 406. STIs 413-1 and 413-2 can be oxides such as, but not limited to, a silicon oxide.

Gate dielectrics 407-1, 407-2, and 407-3 can be, but are not limited to, high-k dielectrics such as, but not limited to, high-k dielectric oxides. Gate dielectrics 407-1, 407-2, and 407-3 can be multi-layer dielectrics. For example, a multi-layer dielectric can be realized by an interlayer (IL) such as, but not limited to, silicon oxide (SiOₓ) and a high-k dielectric. Other formats for a multi-layer dielectric can be used. A high-k dielectric, in a single layer or in a multi-layer structure, can include hafnium oxide (HfOₓ), zirconium oxide (ZrOₓ), or another high-k dielectric.

Gates 408-1, 408-2, 408-3 can be metal gates. The metal of the metal gates can be titanium nitride or combinations with other metals, such as lanthanum. With gates 408-1, 408-2, 408-3 on and contacting gate dielectrics 407-1, 407-2, and 407-3, respectively, gate stacks 415-1, 415-2, and 415-3 include high-k metal gates. In an alternate design, gate stacks 415-1, 415-2, and 415-3 can include polysilicon gates rather than metal gates or HKMGs.

Dielectric caps 418-1, 418-2, and 418-3 have been formed on metal contacts 411-1, 411-2, and 411-3 of gate stacks 415-1, 415-2, and 415-3, respectively. A spacer 412 has been formed on gate stacks 415-1, 415-2, and 415-3, on the exposed surfaces of structures between gate stacks 415-1, 415-2, and 415-3, and on the top exposed surface of substrate 401. Spacer 412 is on and contacting the sidewalls of gate stacks 415-1, 415-2, and 415-3 along with being on and contacting top surfaces of STIs 413-1 and 413-2 and the top surface the SiGe region between STIs 413-1 and 413-2 that extend outside of gate stack 415-2. Spacer 412 can be a nitride or other appropriate material to provide insulation and processing protection for gate stacks 415-1, 415-2, and 415-3. The nitride can be, but is not limited to, silicon nitride (SiNₓ).

LDD regions 416-1 and Halo regions 417-1 have been formed for transistor 402-1. LDD regions 416-2 and Halo regions 417-2 have been formed for transistor 402-2. LDD regions 416-3 and Halo regions 417-3 have been formed for transistor 402-3. Formation of these LDD and Halo region was performed by implantation through spacer 412. For transistor 402-1, implants have been made by implant injection 422. For transistor 402-2, implants have been made by implant injection 426. For transistor 402-3, implants have been made by implant injection 428. Implant injection 428, implant injection 426, and implant injection 422 can have different characteristics from each other. The different characteristic can be based on the transistor types of transistors 402-1, 402-2, and 402-3 and the electronic device in which the transistors are being formed. For example, transistor 402-1 can be formed as a NMOS transistor, transistor 402-2 can be formed as a PMOS transistor with SiGe in active regions, and transistor 402-3 can formed as a NMOS transistor, a PMOS transistor without eSiGe, or a PMOS transistor with a cSiGe but without eSiGe. Transistor 402-3 can be formed as a component of a pitch circuit of a periphery to a memory region of a memory device. Transistors 402-1 and 402-2 can be formed as a component of a periphery circuit of the periphery to the memory region of the memory device. The memory device can be, but is not limited to, a DRAM device. With the LDD and Halo regions formed by implant through spacer 412 avoiding exposing the surfaces of substrate 401, STIs 413-1 and 413-2, and the SiGe region between STIs 413-1 and 413-2, surface oxidation of the active area for transistors 402-1, 402-2, and 402-3 can be avoided. With spacer 412 etched from these regions, as is performed in conventional processing, a 3 nm to 5 nm oxide may be formed on such surfaces, leading to reduced performance of transistor 402-2 to be structured with a cSiGe and eSiGe source/drains, which can be avoided by the use of implantation through spacer 412.

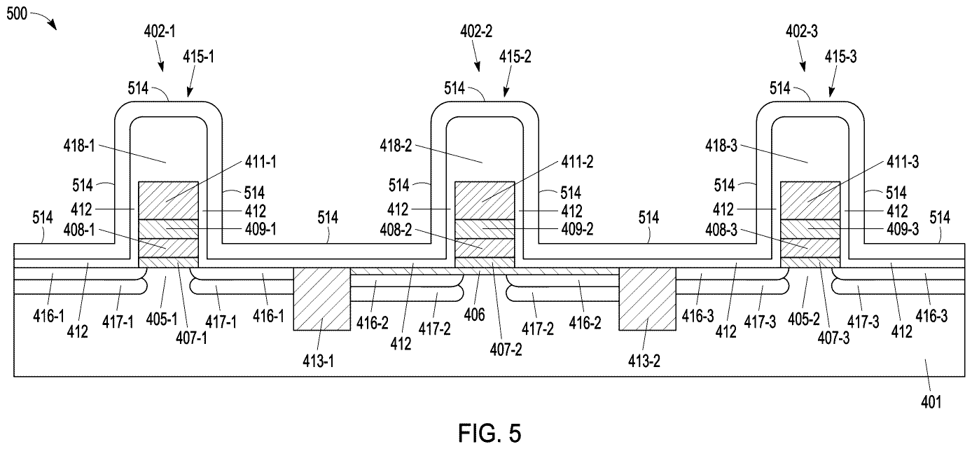

FIG. 5 illustrates a cross-sectional view of a structure 500 after processing structure 400 of FIG. 4. A hard mask 514 has been formed on spacer 412, forming a second spacer for the process flow. The material of hard mask 514 can be the same material of spacer 412. Both hard mask 514 and spacer 412 can be, but are not limited to, nitrides.

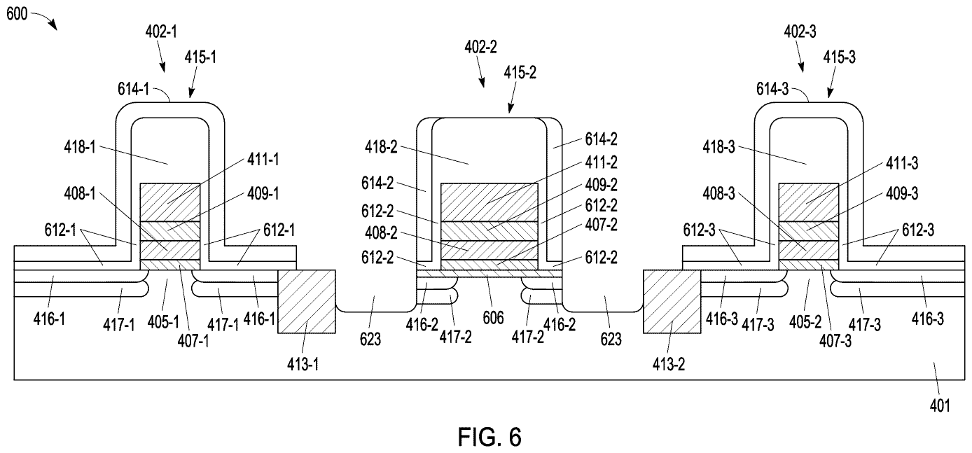

FIG. 6 illustrates a cross-sectional view of a structure 600 after processing structure 500 of FIG. 5. Photolithography has been used to form a resist patten. Using the resist pattern, material has been removed from structure 500, creating cavities 623 in which eSiGe can be formed. The resist pattern and material removal has reduced hard mask 514 of structure 500 by removing material of hard mask 514 from on top of dielectric cap 418-2 of gate stack 415-2 of transistor 402-2. The material removal has modified spacer 412 into spacers 612-1, 612-2, and 612-3 and modified hard mask 514 into sidewalls 614-1, 614-2, and 614-3. The material removal can be conducted using a dry etch. While modifying components for transistor 402-2, the components for transistors 402-1 and 402-3 have been covered by the resist pattern during material removal so that transistors 402-1 and 402-3 are not altered.

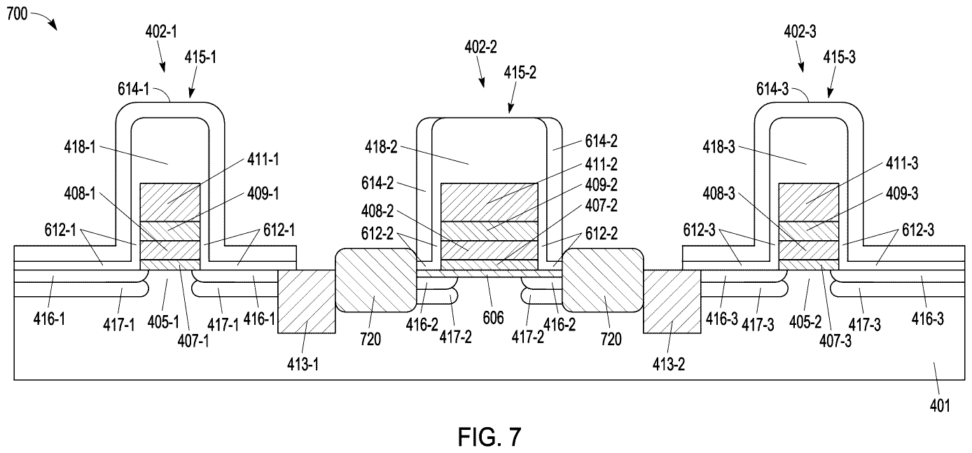

FIG. 7 illustrates a cross-sectional view of a structure 700 after processing structure 600 of FIG. 6. Two eSiGe regions 720 have been grown in cavities 623 of structure 600 of FIG. 6. The eSiGe growth can be performed by selective epitaxy. The two eSiGe regions 720 are connected to each other by cSiGe structure 606 that has portions extending from the region of cSiGe structure 406 that is directly under gate dielectric 407-2. The two eSiGe regions 720 form source/drain regions for transistor 402-2 being constructed. The two eSiGe regions 720 can be a multi-layer structure and may be in-situ doped with boron (B).

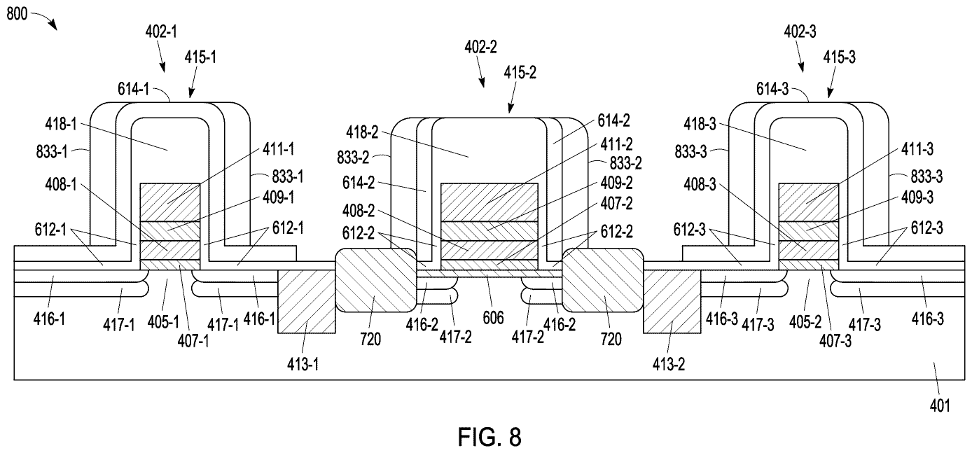

FIG. 8 illustrates a cross-sectional view of a structure 800 after processing structure 700 of FIG. 7. An oxide has been formed on the exposed surfaces of structure 700. The oxide formed has been etched, forming spacer oxide 833-1 on the sidewalls 614-1 of gate stack 415-1, forming spacer oxide 833-2 on the sidewalls 614-2 of gate stack 415-2, and forming spacer oxide 833-3 on the sidewalls 614-3 of gate stack 415-3.

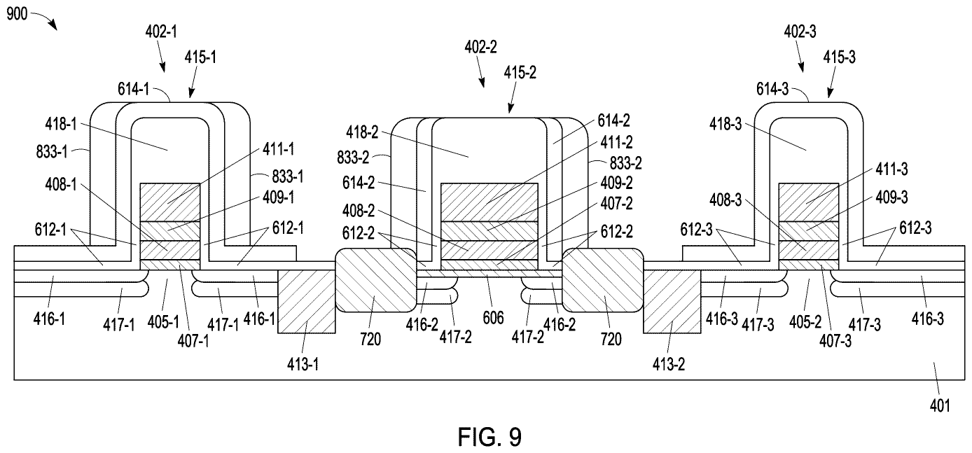

FIG. 9 illustrates a cross-sectional view of a structure 900 after processing structure 800 of FIG. 8. Photolithography has been used to form a resist patten. Using the resist pattern, spacer oxide 833-3 has been removed from sidewalls 614-3 of gate stack 415-3, providing the formation of transistor 402-3 as an open pitch device material. The removal of spacer oxide 833-3 can be conducted using an appropriate etch.

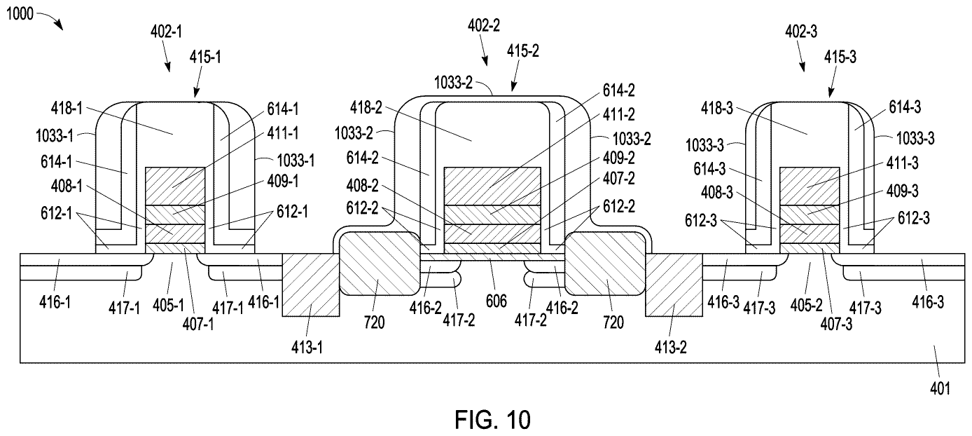

FIG. 10 illustrates a cross-sectional view of a structure 1000 after processing structure 900 of FIG. 9. An oxide has been formed on the exposed surfaces of structure 900 and patterned by photolithography to cover transistor 402-2, forming spacer oxide 1033-2, which can include 833-2 previously formed. The oxide and extensions of sidewalls 614-1 and 614-3 and spacers 612-1 and 612-3 have been etched forming spacer oxide 1033-1 on sidewall 614-1 of gate stack 415-1 and spacer oxide 1033-3 on sidewall 614-3 of gate stack 415-3. Spacer oxide 1033-1 can include spacer oxide 833-1 that was previous formed.

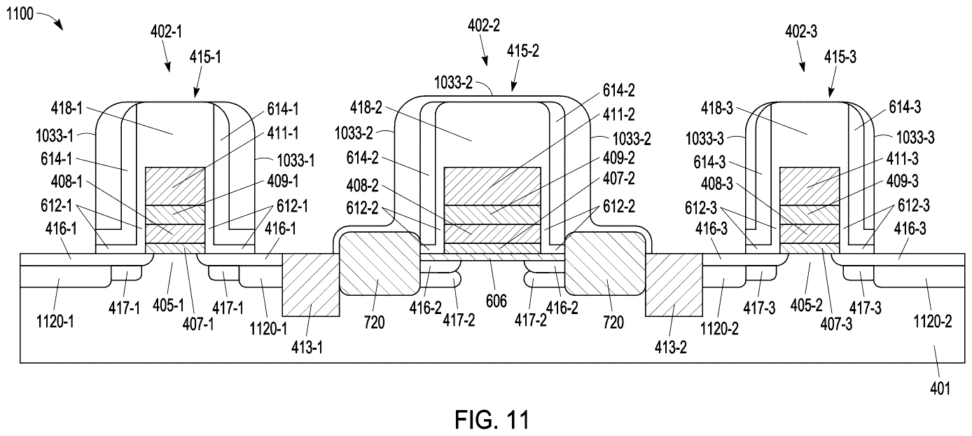

FIG. 11 illustrates a cross-sectional view of a structure 1100 after processing structure 1000 of FIG. 10. Source/drains 1120-1 have been formed for transistor 402-1. Source/drains 1120-2 have been formed for transistor 402-3. Other transistors in the electronic device being fabricated can be formed in the same manner as one or more of transistors 402-1, 402-2, and 402-3. Depending on the design of the integrated circuit being formed, such additional transistors can be formed in the same process flow. The transistors can be formed in periphery circuits or pitch circuits of a memory array of a memory device, such as but not limited to a DRAM device.

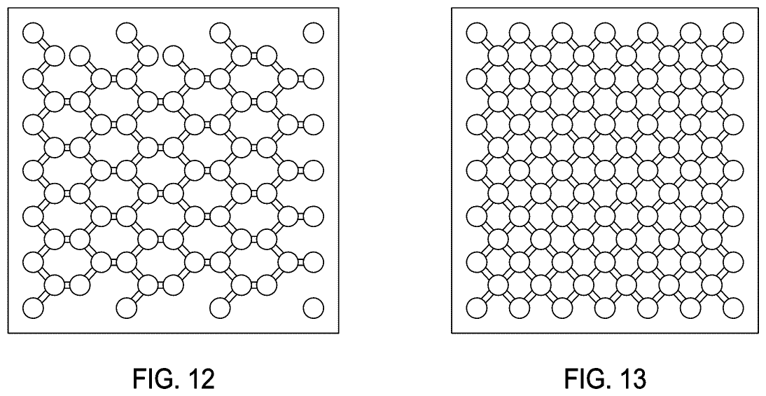

Structures 400-1100 can be implemented in a Si (100) substrate with the channels structured in the <110> direction or in the <100> direction. FIG. 12 represents the lattice structure for a Si (100) substrate in the <110> direction. FIG. 13 represents the lattice structure for the Si (100) substrate in the <100> direction. With the <110> direction as a reference, the structure can be taken to be 0° wafer. The structure of FIG. 13 can be attained by rotating the structure of FIG. 12 by 45°, which can then be taken to be a 45° wafer.

Various deposition techniques for components of structures 400-1100 in the process flow of FIGS. 4-11 can be used that are typical for the material being formed, the dimensions of the material being formed, and the architecture in which the material is being formed. Selective etching can be used to remove selected regions in some of the processing discussed herein. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in various material removal procedures, as taught herein.

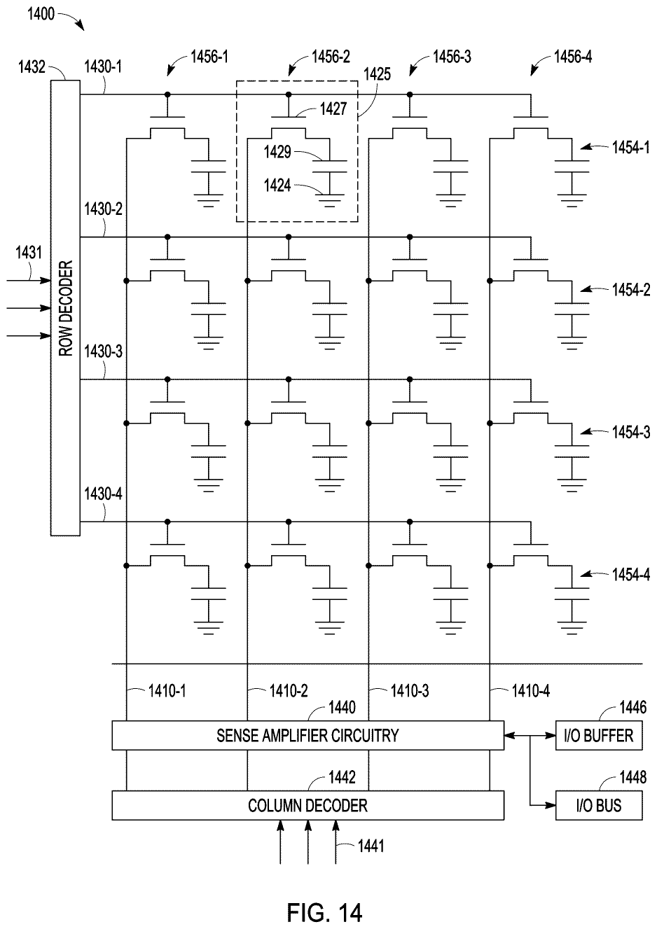

FIG. 14 is a schematic of an embodiment of an example DRAM device 1400 that can include an architecture in which transistors in the periphery to the memory array of DRAM device 1400 are structured with spacers on and contacting sidewalls of the gate stacks of the transistors without divots to the active areas of the transistors underneath the spacers, as taught herein. The lack of divots provides the contact of the spacers to the active areas without an oxide or with a native oxide that has a thickness of about one nanometer and provides a uniform channel-structure-to-drain interface. DRAM device 1400 can include an array of memory cells 1425 (only one being labeled in FIG. 14 for ease of presentation) arranged in rows 1454-1, 1454-2, 1454-3, and 1454-4 and columns 1456-1, 1456-2, 1456-3, and 1456-4. For simplicity and ease of discussion, the array is shown in only two dimensions, but the array can be extended into the third dimension. Further, while only four rows 1454-1, 1454-2, 1454-3, and 1454-4 and four columns 1456-1, 1456-2, 1456-3, and 1456-4 of four memory cells are illustrated, DRAM devices like DRAM device 1400 can have significantly more memory cells 1425 (e.g., tens, hundreds, or thousands of memory cells) per row or per column.

Each memory cell 1425 can include a single transistor 1427 and a single capacitor 1429, which is commonly referred to as a 1T1C (one-transistor—one capacitor cell). One plate of capacitor 1429, which can be termed the “node plate,” is connected to the drain terminal of transistor 1427, whereas the other plate of the capacitor 1429 is connected to a reference 1424, which can be ground. Each capacitor 1429 within the array of 1T1C memory cells 1425 typically serves to store one bit of data, and the respective transistor 1427 serves as an access device to write to or read from storage capacitor 1429.

The transistor gate terminals within each row of rows 1454-1, 1454-2, 1454-3, and 1454-4 are portions of respective WLs 1430-1, 1430-2, 1430-3, and 1430-4 (for example, word lines), and the transistor source terminals within each of columns 1456-1, 1456-2, 1456-3, and 1456-4 are electrically connected to respective DLs 1410-1, 1410-2, 1410-3, and 1410-4 (for example bit lines). A row decoder 1432 can selectively drive the individual WLs 1430-1, 1430-2, 1430-3, and 1430-4, responsive to row address signals 1431 input to row decoder 1432. Transistors within row decoder 1432 can be structured as taught herein. Driving a given WL at a high voltage causes the access transistors within the respective row to conduct, thereby connecting the storage capacitors within the row to the respective DLs, such that charge can be transferred between the DLs and the storage capacitors for read or write operations. Both read and write operations can be performed via sense amplifier circuitry 1440, which can transfer bit values between the memory cells 1425 of the selected row of the rows 1454-1, 1454-2, 1454-3, and 1454-4 and input/output buffers 1446 (for write/read operations) or external input/output data buses 1448. Transistors within sense amplifier circuitry 1440 can be structured as taught herein.

A column decoder 1442 responsive to column address signals 1441 can select which of the memory cells 1425 within the selected row is read out or written to. Transistors within column decoder 1442 can be structured as taught herein. Alternatively, for read operations, the storage capacitors 1429 within the selected row may be read out simultaneously and latched, and the column decoder 1442 can then select which latch bits to connect to the output data bus 1448. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 1400 may be implemented as an integrated circuit within a package that includes pins for receiving supply voltages (e.g., to provide the source and gate voltages for the transistors 1427) and signals (including data, address, and control signals). FIG. 14 depicts DRAM device 1400 in simplified form to illustrate basic structural components, omitting many details of the memory cells 1425 and associated WLs 1430-1, 1430-2, 1430-3, and 1430-4 and DLs 1410-1, 1410-2, 1410-3, and 1410-4 as well as the peripheral circuitry. For example, in addition to the row decoder 1432 and column decoder 1442, sense amplifier circuitry 1440, and buffers 1446, DRAM device 1400 may include further peripheral circuitry, such as a memory control unit that controls the memory operations based on control signals (provided, e.g., by an external processor), additional input/output circuitry, etc. Transistors within the peripheral circuitry can be structured as taught herein. Details of such peripheral circuitry are generally known to those of ordinary skill in the art and not further discussed herein.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

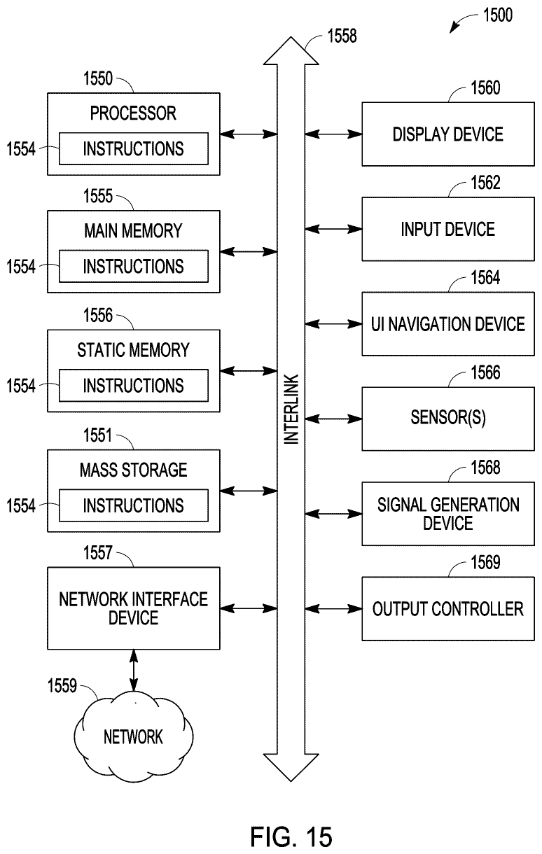

FIG. 15 illustrates a block diagram of an example machine 1500 having one or more embodiments of transistor components as discussed herein, for example in memory devices incorporated in machine 1500. In alternative embodiments, machine 1500 may operate as a standalone device or may be connected (e.g., networked) to other machines. In a networked deployment, machine 1500 may operate in the capacity of a server machine, a client machine, or both in server-client network environments. In an example, machine 1500 may act as a peer machine in peer-to-peer (P2P) (or other distributed) network environment. Machine 1500 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 1500 can include one or more devices having structures with components as discussed with respect to structure 1100 of FIG. 11.

Machine (e.g., computer system) 1500 may include a hardware processor 1550 (e.g., a CPU, a GPU, a hardware processor core, or any combination thereof), a main memory 1555 and a static memory 1556, some or all of which may communicate with each other via an interlink (e.g., bus) 1558. Machine 1500 may further include a display device 1560, an alphanumeric input device 1562 (e.g., a keyboard), and a user interface (UI) navigation device 1564 (e.g., a mouse). In an example, display device 1560, alphanumeric input device 1562, and UI navigation device 1564 may be a touch screen display. Machine 1500 may additionally include a mass storage (e.g., drive unit) 1551, a signal generation device 1568 (e.g., a speaker), a network interface device 1557, and one or more sensors 1566, such as a global positioning system (GPS) sensor, compass, accelerometer, or other sensor. Machine 1500 may include an output controller 1569, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 1500 may include a machine-readable medium on which is stored one or more sets of data structures or instructions 1554 (for example, software or microcode) embodying or utilized by machine 1500. Instructions 1554 may also reside, completely or at least partially, within main memory 1555, within static memory 1556, within mass storage 1551, or within hardware processor 1550 during execution thereof by machine 1500. In an example, one or any combination of hardware processor 1550, main memory 1555, static memory 1556, or mass storage 1551 may constitute machine-readable medium. Machine-readable medium can be a single medium or multiple media (e.g., a centralized or distributed database, or associated caches and servers) configured to store one or more instructions 1554.

The term “machine-readable medium” may include any medium that is capable of storing instructions for execution by machine 1500 and that cause machine 1500 to perform any one or more of the techniques for which machine 1500 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 1554 (e.g., software, programs, microcode, an operating system (OS), etc.) or other data stored on mass storage 1551, can be accessed by main memory 1555 for use by processor 1550. Main memory 1555 (e.g., DRAM) is typically fast, but volatile, and thus a different type of storage than mass storage 1551 (e.g., an SSD), which is suitable for long-term storage, including while in an “off” condition. Instructions 1554 or data in use by a user or machine 1500 are typically loaded in main memory 1555 for use by processor 1550. When main memory 1555 is full, virtual space from mass storage 1551 can be allocated to supplement main memory 1555; however, because mass storage 1551 is typically slower than main memory 1555, and write speeds are typically at least twice as slow as read speeds, use of virtual memory can greatly reduce user experience due to storage device latency (in contrast to main memory 1555, e.g., DRAM). Further, use of mass storage 1551 for virtual memory can greatly reduce the usable lifespan of mass storage 1551.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 1554 may further be transmitted or received over a network 1559 using a transmission medium via network interface device 1557 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1557 may include one or more physical jacks (e.g., Ethernet, coaxial, or phone jacks) or one or more antennas to connect to the communications network 1526. In an example, network interface device 1557 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 1500 or data to or from machine 1500. The transportation can include using digital or analog communications signals that can be transmitted over the transmission medium to facilitate communication of such software or data.

The following example embodiments of devices and methods, in accordance with the teachings herein.
An example electronic device 1 can comprise a transistor having a silicon germanium channel structure and a gate stack with a gate dielectric on the silicon germanium channel structure. The transistor can include a spacer along the gate stack and on extensions of the silicon germanium channel structure that are beyond the gate stack such that that the spacer is structured without an oxide contacting the extensions or with a native oxide having a thickness of less than about one nanometer between and contacting the spacers and the extensions. The transistor can include embedded silicon germanium source/drains contacting the extensions of the silicon germanium channel structure.
An example electronic device 2 can include features of example electronic device 1 and can include the transistor being located in a periphery to a memory array of a memory device.
An example electronic device 3 can include features of example electronic device 2 and any of the preceding example electronic devices and can include the periphery including a n-type transistor having a gate dielectric in a gate stack with a spacer adjacent and contacting the gate stack, the spacer being without an oxide on and contacting LDD regions of the n-type transistor or with a native oxide having a thickness of less than about one nanometer between and contacting the spacer and the LDD regions of the n-type transistor.
An example electronic device 4 can include features of example electronic device 3 and any of the preceding example electronic devices and can include the transistor and the n-type transistor being structured as part of a periphery circuit.
An example electronic device 5 can include features of example electronic device 2 and any of the preceding example electronic devices and can include the periphery including a pitch transistor having a gate dielectric in a gate stack with a spacer adjacent and contacting the gate stack, the spacer being without an oxide on and contacting LDD regions of the pitch transistor or with a native oxide having a thickness of less than about one nanometer between and contacting the spacer and the LDD regions of the pitch transistor.
An example electronic device 6 can include features of any of the preceding example electronic devices and can include the gate dielectric being an oxide in the gate stack with a polysilicon gate on the gate dielectric and a metal on the polysilicon gate or the gate dielectric including a high-k dielectric with the gate stack having a metal gate on the high-k electric.
An example electronic device 7 can include features of any of the preceding example electronic devices and can include the silicon germanium channel structure being oriented in the <100> direction or the <110> direction.
An example electronic device 8 can include features of any of the preceding example electronic devices and can include the spacer including a nitride.
In an example electronic device 9, any of the electronic devices of example electronic devices 1 to 8 may be incorporated into an electronic apparatus further comprising a host processor or memory controller and a communication bus extending between the host processor/memory controller and the memory device.
In an example electronic device 10, any of the electronic devices of example electronic devices 1 to 9 may be modified to include any structure presented in another of example electronic device 1 to 9.
In an example electronic device 11, any apparatus associated with the electronic devices of example electronic devices 1 to 10 may further include a machine-readable storage device configured to store instructions as a physical state, wherein the instructions may be used to perform one or more operations of the apparatus.
In an example electronic device 12, any of the electronic devices of example electronic devices 1 to 11 may be formed or operated in accordance with any of the below example methods 1 to 11 and methods 12 to 16.
An example method 1 of forming an electronic device can comprise forming a transistor including: forming a silicon germanium channel structure; forming a gate stack with a gate dielectric formed on the silicon germanium channel structure; forming spacers along the gate stack and on extensions of the silicon germanium channel structure that are beyond the gate stack such that the spacers are structured without an oxide contacting the extensions or with a native oxide having a thickness of less than about one nanometer between and contacting the spacers and the extensions; and forming embedded silicon germanium source/drains contacting the extensions of the silicon germanium channel structure.
An example method 2 of forming an electronic device can include features of example method 1 of forming an electronic device and can include implanting dopants through an initial spacer on the extensions of the silicon germanium channel structure after forming the gate stack and before forming a second spacer on the extensions of the silicon germanium channel structure.
An example method 3 of forming an electronic device can include features of any of the preceding example methods of forming an electronic device and can include forming the gate stack to include forming a polysilicon region on the gate dielectric or forming the gate dielectric as part of a high-k metal gate.
An example method 4 of forming an electronic device can include features of any of the preceding example methods of forming an electronic device and can include forming the transistor in a periphery circuit of a memory device and forming a n-type transistor in the periphery circuit including forming the n-type transistor having a gate dielectric in a gate stack with a spacer adjacent and contacting the gate stack of the n-type transistor, the spacer being structured without an oxide on and contacting LDD regions of the n-type transistor or with a native oxide having a thickness of less than about one nanometer between and contacting the spacer and the LDD regions of the n-type transistor.
An example method 5 of forming an electronic device can include features of any of the preceding example methods of forming an electronic device and can include forming the transistor in a periphery circuit of a memory device and forming a pitch transistor having a gate dielectric in a gate stack with a spacer adjacent and contacting the gate stack of the pitch transistor, the spacer being structured without an oxide on and contacting LDD regions of the pitch transistor or with a native oxide having a thickness of less than about one nanometer between and contacting the spacer and the LDD regions of the pitch transistor.
In an example method 6, any of the example methods 1 to 5 of forming an electronic device may be performed in forming an electronic apparatus further comprising a host processor and a communication bus extending between the host processor and a memory system.
In an example method 7 of forming an electronic device, any of the example methods 1 to 6 of forming an electronic device may be modified to include operations set forth in any other of example methods 1 to 6.
In an example method 8 of forming an electronic device, any of the example methods 1 to 7 of forming an electronic device may be implemented at least in part through use of instructions stored as a physical state in one or more machine-readable storage devices.
An example method 9 of forming an electronic device can include features of any of the preceding example methods 1 to 8 of forming an electronic device and can include performing functions associated with any features of example electronic devices 1 to 12.
An example method 10 of forming an electronic device can comprise forming a transistor including forming a gate stack on a silicon germanium region, the silicon germanium region in a top surface region of a substrate; forming a spacer on the gate stack and on the silicon germanium region adjacent the gate stack; implanting dopants through the spacer; etching cavities for a source and a drain; forming embedded silicon germanium source and embedded silicon germanium drain in the cavities for the source and the drain, with the embedded silicon germanium source coupled to the embedded silicon germanium drain by a silicon germanium channel structure formed from the silicon germanium region.
An example method 11 of forming an electronic device can include features of example method 10 of forming an electronic device and can include forming a hard mask on the gate stack and on the spacer before forming the cavities for the source and the drain.
An example method 12 of forming an electronic device can include features of example method 11 of forming an electronic device and any of the preceding example method 10 of forming an electronic device and can include patterning the hard mask and forming the cavities for the regions for the source and the drain such that a wall of each cavity includes an end of the silicon germanium region extending from an end of the gate stack.
An example method 13 of forming an electronic device can include features of any of the preceding example methods 10 to 12 of forming an electronic device and can include forming one or more transistors without silicon germanium while forming the transistors such that the one or more transistors have material of the spacer on and contacting LDD regions of the one or more transistors without an oxide on and contacting both the material of the spacer and the LDD regions of the one or more transistors or with a native oxide having a thickness of less than about one nanometer between and contacting the material of the spacer and the LDD regions of the one or more transistors.
An example method 14 of forming an electronic device can include features of example method 13 of forming an electronic device and any of the preceding example methods 10 to 13 of forming an electronic device and can include implanting dopants in the one or more transistors that are different from the dopants implanted through the spacer.
An example method 15 of forming an electronic device can include features of any of the preceding example methods 10 to 14 of forming an electronic device and can include implanting dopants through the spacer to include forming a LDD region and a Halo structure.
An example method 16 of forming an electronic device can include features of any of the preceding example methods 10 to 15 of forming an electronic device and can include forming the gate stack to include forming a high-k metal gate.
In an example method 17 of forming an electronic device, any of the example methods 10 to 17 of forming an electronic device may be performed in forming an electronic apparatus further comprising a host processor and a communication bus extending between the host processor and a memory system.
In an example method 18 of forming an electronic device, any of the example methods 10 to 17 of forming an electronic device may be modified to include operations set forth in any other of example methods 10 to 17 of forming an electronic device.
In an example method 19 of forming an electronic device, any of the example methods 10 to 18 of forming an electronic device may be implemented at least in part through use of instructions stored as a physical state in one or more machine-readable storage devices.
An example method 20 of forming an electronic device can include features of any of the preceding example methods 10 to 19 of forming an electronic device and can include performing functions associated with any features of example electronic devices 1 to 12.

An example machine-readable storage device storing instructions, that when executed by one or more processors, cause a machine to perform operations, can comprise instructions to perform functions associated with any features of example electronic devices 1 to 12 or perform form methods associated with any features of example methods 1 to 9 of forming an electronic device or example methods 10 to 20 of forming an electronic device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. An electronic device comprising:
a transistor having:
a silicon germanium channel structure;
a gate stack with a gate dielectric on the silicon germanium channel structure;
a spacer along the gate stack and on extensions of the silicon germanium channel structure that are beyond the gate stack such that the spacer is structured without an oxide contacting the extensions or with a native oxide having a thickness of less than about one nanometer between and contacting the spacer and the extensions;
embedded silicon germanium source/drains contacting the extensions of the silicon germanium channel structure

2. The electronic device of claim 1, wherein the transistor is located in a periphery to a memory array of a memory device.

3. The electronic device of claim 2, wherein the periphery includes a n-type transistor having a gate dielectric in a gate stack with a spacer adjacent and contacting the gate stack, the spacer being without an oxide on and contacting lightly doped drain (LDD) regions of the n-type transistor or with a native oxide having a thickness of less than about one nanometer between and contacting the spacer and the LDD regions of the n-type transistor.

4. The electronic device of claim 3, wherein the transistor and the n-type transistor structured as part of a periphery circuit.

5. The electronic device of claim 2, wherein the periphery includes a pitch transistor having a gate dielectric in a gate stack with a spacer adjacent and contacting the gate stack, the spacer being without an oxide on and contacting lightly doped drain (LDD) regions of the pitch transistor or with a native oxide having a thickness of less than about one nanometer between and contacting the spacer and the LDD regions of the pitch transistor.

6. The electronic device of claim 1, wherein the gate dielectric is an oxide with the gate stack having a polysilicon gate on the gate dielectric and a metal on the polysilicon gate or the gate dielectric includes a high-k dielectric with the gate stack having a metal gate on the high-k electric.

7. The electronic device of claim 1, wherein the silicon germanium channel structure is in a <100> direction or a <110> direction.

8. The electronic device of claim 1, wherein the spacer includes a nitride.

9. A method of forming an electronic device, the method comprising:
forming a transistor including:
forming a silicon germanium channel structure;
forming a gate stack with a gate dielectric formed on the silicon germanium channel structure;
forming spacers along the gate stack and on extensions of the silicon germanium channel structure that are beyond the gate stack such that the spacers are structured without an oxide contacting the extensions or with a native oxide having a thickness of less than about one nanometer between and contacting the spacers and the extensions; and
forming embedded silicon germanium source/drains contacting the extensions of the silicon germanium channel structure.

10. The method of claim 9, wherein the method includes implanting dopants through an initial spacer on the extensions of the silicon germanium channel structure after forming the gate stack and before forming a second spacer on the extensions of the silicon germanium channel structure.

11. The method of claim 9, wherein forming the gate stack includes forming a polysilicon region on the gate dielectric or forming the gate dielectric as part of a high-k metal gate.

12. The method of claim 9, wherein the method includes forming the transistor in a periphery circuit of a memory device and forming a n-type transistor in the periphery circuit including forming the n-type transistor having a gate dielectric in a gate stack with a spacer adjacent and contacting the gate stack of the n-type transistor, the spacer being structured without an oxide on and contacting lightly doped drain (LDD) regions of the n-type transistor or with a native oxide having a thickness of less than about one nanometer between and contacting the spacer and the LDD regions of the n-type transistor.

13. The method of claim 9, wherein the method includes forming the transistor in a periphery circuit of a memory device and forming a pitch transistor having a gate dielectric in a gate stack with a spacer adjacent and contacting the gate stack of the pitch transistor, the spacer being structured without an oxide on and contacting lightly doped drain (LDD) regions of the pitch transistor or with a native oxide having a thickness of less than about one nanometer between and contacting the spacer and the LDD regions of the pitch transistor.

14. A method of forming an electronic device, the method comprising:
forming a transistor including
forming a gate stack on a silicon germanium region, the silicon germanium region in a top surface region of a substrate;
forming a spacer on the gate stack and on the silicon germanium region adjacent the gate stack;
implanting dopants through the spacer;
etching cavities for a source and a drain;
forming embedded silicon germanium source and embedded silicon germanium drain in the cavities for the source and the drain, with the embedded silicon germanium source coupled to the embedded silicon germanium drain by a silicon germanium channel structure formed from the silicon germanium region.

15. The method of claim 14, wherein the method includes forming a hard mask on the gate stack and on the spacer before forming the cavities for the source and the drain.

16. The method of claim 15, wherein the method includes patterning the hard mask and forming the cavities for the source and the drain such that a wall of each cavity includes an end of the silicon germanium region extending from an end of the gate stack.

17. The method of claim 14, wherein the method includes forming one or more transistors without silicon germanium while forming the transistor such that the one or more transistors have material of the spacer on and contacting lightly doped drain (LDD) regions of the one or more transistors without an oxide on and contacting both the material of the spacer and the LDD regions of the one or more transistors or with a native oxide having a thickness of less than about one nanometer between and contacting the material of the spacer and the LDD regions of the one or more transistors.

18. The method of claim 17, wherein the method includes implanting dopants in the one or more transistors that are different from the dopants implanted through the spacer.

19. The method of claim 14, wherein implanting dopants through the spacer includes forming a lightly doped drain region and a Halo structure.

20. The method of claim 14, wherein forming the gate stack includes forming a high-k metal gate.
